(19) United States
(12) Patent Application Publication
(10) Pub. No.: US 2025/0241086 A1
(43) Pub. Date: Jul. 24, 2025

(54) STRUCTURE AND FORMATION METHOD OF SEMICONDUCTOR DEVICE WITH PHOTO-SENSING STRUCTURE

(71) Applicant: Taiwan Semiconductor Manufacturing Company, Ltd., Hsinchu (TW)

(72) Inventors: Chen-Hao CHIANG, Taoyuan City (TW); Li-Weng CHANG, New Taipei City (TW); Jiun-Yi WU, Taoyuan City (TW); Chen-Hua YU, Hsinchu City (TW)

(21) Appl. No.: 18/421,096

(22) Filed: Jan. 24, 2024

(51) Int. Cl. H01L 31/0203; H01L 31/028; H01L 31/18

(52) U.S. Cl. CPC H10F 77/50; H10F 71/1215; H10F 77/122

(57) ABSTRACT

A semiconductor device structure and a formation method are provided. The method includes forming a p-type doped structure and an n-type doped structure. The method also includes forming a photo-sensing structure, and a portion of the photo-sensing structure is between the p-type doped structure and the n-type doped structure. The method further includes forming a semiconductor cap over the photo-sensing structure. The semiconductor cap is p-type doped.

### BACKGROUND

The semiconductor integrated circuit (IC) industry has experienced rapid growth. Technological advances in IC materials and design have produced generations of ICs. Each generation has smaller and more complex circuits than the previous generation. Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

Silicon photonic devices may be made using existing semiconductor fabrication techniques. It is possible to create hybrid devices in which the optical and electronic components are integrated onto a single semiconductor chip. Silicon photonic devices are being actively developed and researched by using optical interconnects to provide faster data transfer both between and within semiconductor chips.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1I are cross-sectional views of a process for forming a portion of a semiconductor device structure, in accordance with some embodiments.

FIG. 2 is a cross-sectional view of a portion of a semiconductor device structure, in accordance with some embodiments.

FIG. 3 shows a portion of a process chamber used in a process for forming a portion of a semiconductor device structure, in accordance with some embodiments.

FIG. 4 is a cross-sectional view of a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure relate to a semiconductor device structure with one or more photodetectors. A photodetector is an optoelectronic device that is configured to receive photons of incident radiation and convert the photons into an electrical signal. Photodetectors may have many applications such as light detection devices, lidar devices, optical communication devices, image sensor devices, and the like.

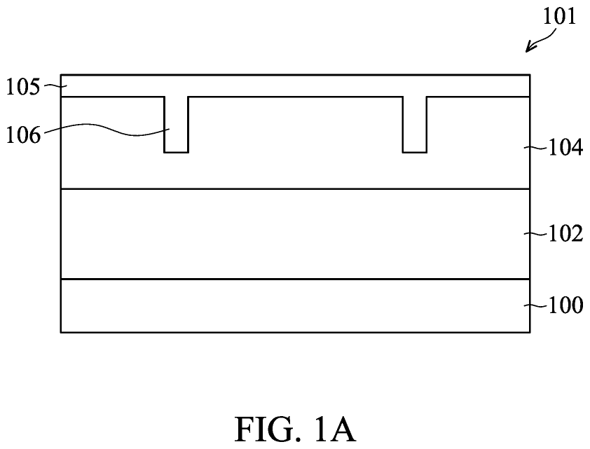

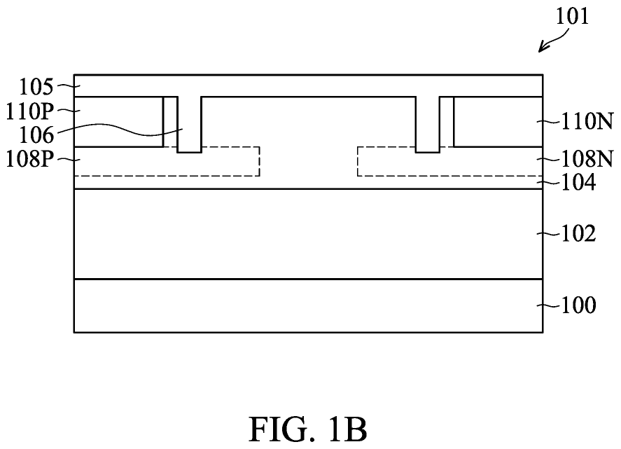

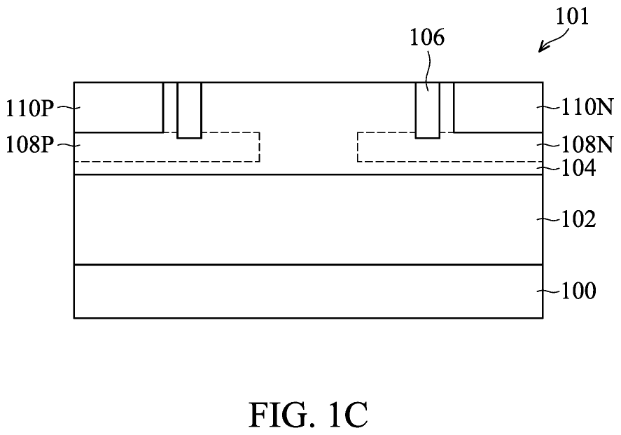

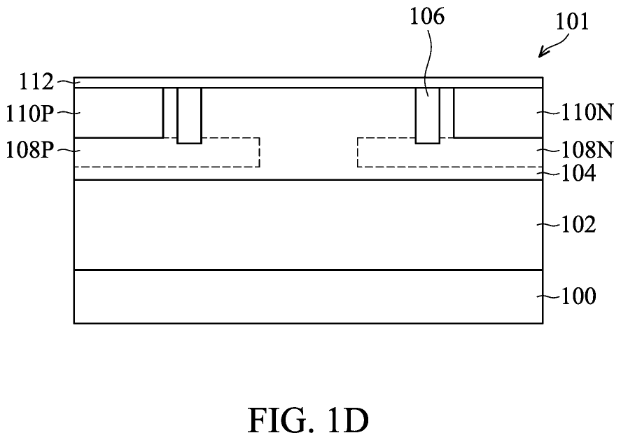

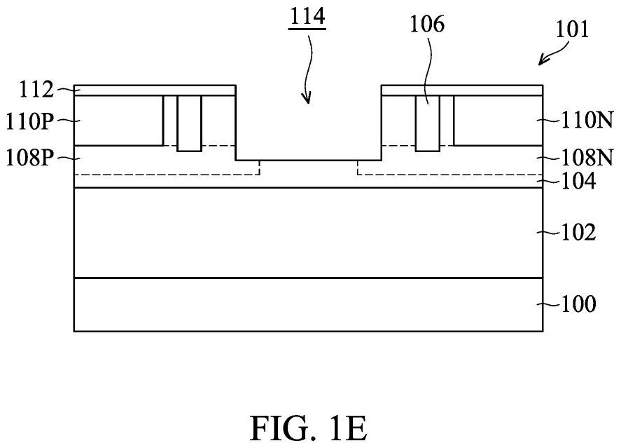

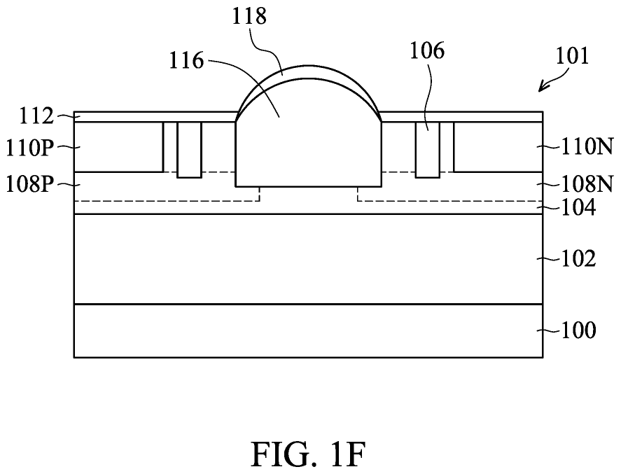

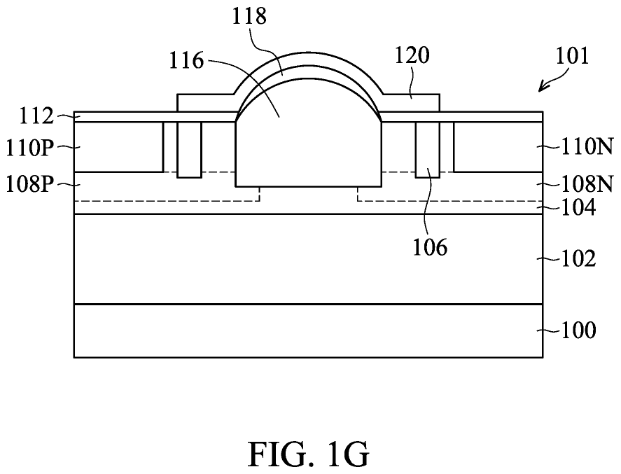

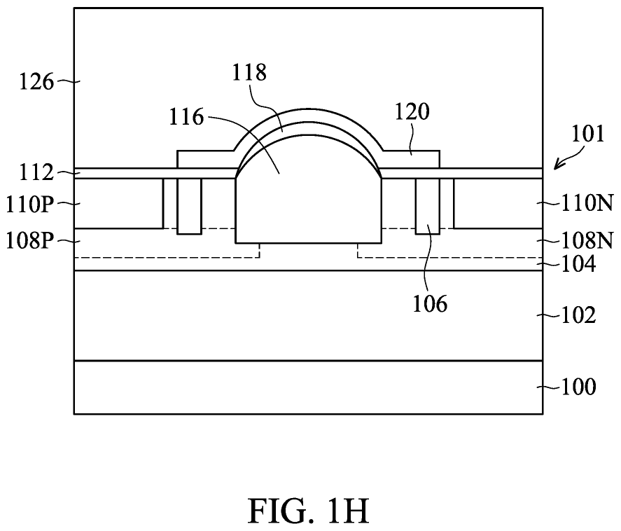

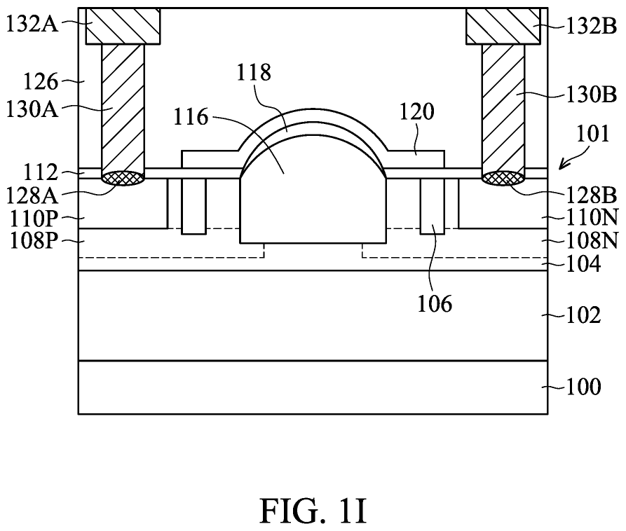

FIGS. 1A-1I are cross-sectional views of a process for forming a portion of a semiconductor device structure, in accordance with some embodiments. As shown in FIG. 1A, a semiconductor substrate 101 is received or provided. In some embodiments, the semiconductor substrate 101 is a bulk semiconductor substrate, such as a semiconductor wafer. The semiconductor substrate 101 may include silicon or other elementary semiconductor materials such as germanium. In some embodiments, the semiconductor substrate 101 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 101 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 101 is a semiconductor-on-insulator (SOI) substrate. In some embodiments, the semiconductor substrate 101 includes a support substrate 100, a dielectric layer 102, and a semiconductor layer 104, as shown in FIG. 1A. The support substrate 100 may be made of a semiconductor material such as silicon. The dielectric layer 102 may be made of an oxide material such as silicon oxide. The semiconductor layer 104 may include a semiconductor material such as silicon. The SOI substrate may be fabricated using a separation by implantation of oxygen (SIMOX) process, a wafer bonding process, another applicable method, or a combination thereof.

As shown in FIG. 1A, multiple isolation structures 106 are formed in the semiconductor layer 104 of the semiconductor substrate 101, in accordance with some embodiments. The isolation structures 106 may be used to define various active regions in the semiconductor substrate 101 and to electrically isolate neighboring elements (such as n-type doped regions and p-type doped regions) from one another. The isolation structures 106 may be made of or include silicon oxide, silicon nitride, silicon oxynitride, fluoride-doped silicate glass (FSG), a low-K dielectric material, another suitable material, or a combination thereof. The isolation structures 106 may be formed by using an isolation technology, such as local oxidation of semiconductor (LOCOS), shallow trench isolation (STI), or the like.

In some embodiments, the formation of the isolation structures 106 includes patterning the semiconductor layer 104 of the semiconductor substrate 101 by a photolithography process, etching a trench in the semiconductor substrate 101 (for example, by using a dry etching, wet etching, plasma etching process, or a combination thereof), and filling the trench (for example, by using a chemical vapor deposition process) with one or more insulating layers. In some embodiments, an insulating layer 105 is deposited to overfill the trench, as shown in FIG. 1A. The portions of the insulating layer 105 that are laterally surrounded by the semiconductor layer 104 form the isolation structures 106. In some embodiment, the filled trench may have a multi-layer structure, such as a thermal oxide liner layer filled with silicon nitride or silicon oxide.

As shown in FIG. 1B, multiple doped structures 108P, 110P, 108N, and 110N are formed in the semiconductor layer 104 of the semiconductor substrate 101, in accordance with some embodiments. In some embodiments, the doped structures 108P and 110P are p-type doped regions formed in the semiconductor layer 104. The doped structures 108P and 110P include p-type dopants such as boron (B), gallium (Ga), indium (In), and/or another suitable dopant. In some embodiments, the dopant concentration of the doped structure 110P is higher than that of the doped structure 108P.

In some embodiments, the doped structures 108N and 110N are n-type doped regions formed in the semiconductor layer 104. The doped structures 108N and 110N include n-type dopants such as phosphor (P), antimony (Sb), arsenic (As), and/or another suitable dopant. In some embodiments, the dopant concentration of the doped structure 110N is higher than that of the doped structure 108N.

In some embodiments, multiple ion implantation processes are sequentially performed to sequentially form the doped structures 108P, 110P, 108N, and 110N. Multiple mask elements are used during the ion implantation processes, so as to selectively implant dopants into selective areas. As a result, the doped structures 108P, 110P, 108N, and 110N are formed. One or more annealing processes may be used to activate the dopants. For example, a rapid thermal annealing process is used.

As shown in FIG. 1C, the portion of the insulating layer 105 that is outside of the trenches is removed, in accordance with some embodiments. A planarization process may be used to remove the portion of the insulating layer 105 that is outside of the trenches. The remaining portions of the insulating layer 105 form the isolation structures 106, as shown in FIG. 1C. The planarization process may include a chemical mechanical polishing (CMP) process, a mechanical grinding process, an etching process, another applicable process, or a combination thereof.

During the multiple ion implantation processes used for forming the doped structures 108P, 110P, 108N, and 110N, the quality of the upper portion of the insulating layer 105 might be negatively affected. Therefore, the planarization process may be used to remove the damaged portion of the insulating layer 105.

As shown in FIG. 1D, a protective layer 112 is deposited over the semiconductor substrate 101 to protect the elements underneath. The protective layer 112 may be made of or include an oxide material such as silicon oxide. The protective layer 112 may be deposited using a chemical vapor deposition (CVD) process, an atomic layer deposition (ALD) process, another applicable process, or a combination thereof.

As shown in FIG. 1E, the protective layer 112 is partially removed, in accordance with some embodiments. One or more photolithography processes and one or more etching processes may be used to pattern the protective layer 112. The protective layer 112 that is patterned may function as an etching mask to assist in the subsequent formation of one or more recesses.

Afterwards, the semiconductor layer 104 of the semiconductor substrate 101 is partially removed to form a recess 114, as shown ion FIG. 1E in accordance with some embodiments. In some embodiments, the recess 114 is a trench. The recess 114 exposes a portion of the doped structure 108P that is p-type doped and a portion of the doped structure 108N that is n-type doped. In some embodiments, the doped structures 108P and 108N are also partially removed during the formation of the recess 114. As a result, the recess 114 extends into the doped structures 108P and 108N. One or more etching processes may be used to form the recess 114.

As shown in FIG. 1F, a photo-sensing structure 116 and a semiconductor cap 118 are sequentially formed to fill the recess 114, in accordance with some embodiments. In some embodiments, the photo-sensing structure 116 and the semiconductor cap 118 are epitaxially grown. In some embodiments, the photo-sensing structure 116 and the semiconductor cap 118 are epitaxially grown in-situ in the same process chamber. In some embodiments, edges of the semiconductor cap 118 and the photo-sensing structure 116 are vertically aligned with each other.

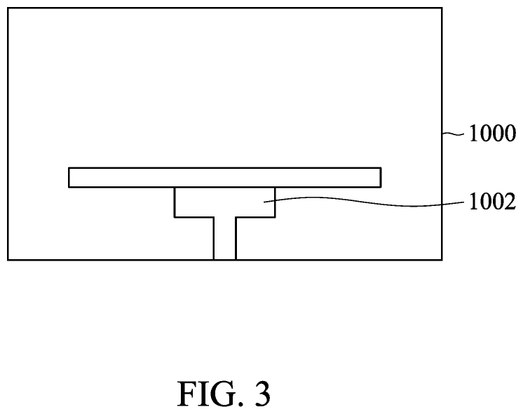

FIG. 3 shows a portion of a process chamber 1000 used in a process for forming a portion of a semiconductor device structure, in accordance with some embodiments. In some embodiments, the process chamber 1000 has a substrate holder 1002. The substrate holder 1002 may be used to hold and secure a substrate such as a wafer. For example, a wafer that includes the structure shown in FIG. 1E may be placed on the substrate holder 1002. Afterwards, multiple processes may be performed to the wafer within the process chamber 1000.

In some embodiments, the photo-sensing structure 116 and the semiconductor cap 118 are sequentially epitaxially grown in-situ in the process chamber 1000. Each of the photo-sensing structure 116 and the semiconductor cap 118 may be formed using a selective epitaxial growth (SEG) process, a chemical vapor deposition (CVD) process (e.g., a vapor-phase epitaxy (VPE) process, a low-pressure chemical vapor deposition (LPCVD) process, an ultra-high vacuum CVD (UHV-CVD) process), a molecular beam epitaxy process, one or more other applicable processes, or a combination thereof. In some embodiments, the semiconductor cap 118 is selectively formed on the photo-sensing structure 116. The formation of the semiconductor cap 118 does not involve any photolithography process and etching process. The fabrication cost and time are significantly reduced.

In some embodiments, the vacuum of the process chamber 1000 is not broken during the epitaxial growth of the photo-sensing structure 116 and the semiconductor cap 118. The formation of the photo-sensing structure 116 and the semiconductor cap 118 is thus prevented from being negatively affected by the environment outside of the process chamber 1000. For example, the surfaces of these elements may be prevented from being oxidized by moisture outside of the process chamber 1000. The interface between the neighboring elements may thus have good quality and low defect density. The reliability and quality of these elements are improved.

In some embodiments, the photo-sensing structure 116 is epitaxially grown on the sidewalls and bottom of the recess 114. In some embodiments, the photo-sensing structure 116 is a germanium-based epitaxial structure. In some embodiments, the photo-sensing structure 116 is made of or includes germanium. In some embodiments, the photo-sensing structure 116 is substantially free of the p-type dopants and the n-type dopants that are included in the doped structures 108P, 110P, 108N, and 110N. In some embodiments, the photo-sensing structure 116 is intrinsic without being doped with any n-type dopants or p-type dopants. The photo-sensing structure 116 may have a thickness that is within a range from about 100 nm to about 2 μm.

In some embodiments, the upper portion of the photo-sensing structure 116 protrudes from the top surface of the semiconductor substrate 101, as shown in FIG. 1F. In some embodiments, the photo-sensing structure 116 has a curved top surface. In some embodiments, the curvature center of the curved top surface of the photo-sensing structure 116 is positioned between the curved top surface and the bottom surface of the semiconductor substrate 101. In some embodiments, the curvature center of the curved top surface of the photo-sensing structure 116 is positioned within the photo-sensing structure 116. In some embodiments, the bottommost surface of the photo-sensing structure 116 is positioned at a higher level than the bottommost surfaces of the doped structures 108P, 110P, 108N, and 110N, as shown in FIG. 1F.

Afterwards, the semiconductor cap 118 is epitaxially grown on the photo-sensing structure 116, as shown in FIG. 1F in accordance with some embodiments. In some embodiments, the semiconductor cap 118 is p-type doped. The semiconductor cap 118 with p-type dopants may help to reduce and/or prevent dark current generated due to the interface defect between the semiconductor cap 118 and the photo-sensing structure 116. The performance and reliability of the photo-sensing structure 116 are significantly improved. The semiconductor cap 118 may be a p-type doped semiconductor layer such as a p-type doped silicon layer. The semiconductor cap 118 may have a thickness that is within a range from about 5 nm to about 50 nm.

The p-type dopants in the semiconductor cap 118 may include boron (B), indium (In), gallium (Ga), another suitable dopant, or a combination thereof. The p-type dopant concentration of the semiconductor cap 118 may be within a range from about 10¹⁷ cm⁻³ to about 10¹⁹ cm⁻³. In some cases, if the p-type dopant concentration of the semiconductor cap 118 is lower than about 10¹⁷ cm⁻³, the amount of the p-type dopants may not be sufficient. The dark current may be high. In some other cases, if the p-type dopant concentration of the semiconductor cap 118 is higher than about 10¹⁹ cm⁻³, there may be too much p-type dopants, which may cause undesired defects.

In some embodiments, the semiconductor cap 118 is in direct contact with the photo-sensing structure 116. In some embodiments, the semiconductor cap 118 extends conformally along the curved top surface of the photo-sensing structure 116. In some embodiments, the semiconductor cap 118 also has a curved top surface, as shown in FIG. 1F.

In some embodiments, the semiconductor cap 118 is epitaxially grown in-situ in the process chamber 1000 where the photo-sensing structure 116 is grown. The vacuum of the process chamber 1000 is not broken during the epitaxial growth of the photo-sensing structure 116 and the semiconductor cap 118. The semiconductor cap 118 is epitaxially grown in-situ in the process chamber 1000 right after the growth of the photo-sensing structure 116. Without being taken out of the process chamber 1000, the surface of the photo-sensing structure 116 is prevented from being oxidized before the subsequent growth of the semiconductor cap 118.

In some embodiments, there is no oxide layer or oxide element formed between the semiconductor cap 118 and the photo-sensing structure 116. The interface quality between the semiconductor cap 118 and the photo-sensing structure 116 is thus ensured, which significantly reduce the amounts of defects. The performance and reliability of the photo-sensing structure 116 are greatly improved.

The semiconductor cap 118 may also be used to prevent germanium in the photo-sensing structure 116 from diffusing into the elements around the photo-sensing structure 116 or the processing tool used for forming the semiconductor device structure. The performance and reliability of the semiconductor device structure may therefore be improved.

As shown in FIG. 1G, a protective element 120 is formed over the semiconductor cap 118, in accordance with some embodiments. In some embodiments, the protective element 120 laterally extends past the opposite edges of the photo-sensing structure 116. In some embodiments, the protective element 120 laterally extends past the opposite edges of the semiconductor cap 118.

In some embodiments, the protective element 120 is a dielectric protective element. The protective element 120 may be made of or includes an oxide material, a nitride material, another suitable material, or a combination thereof. The protective element 120 may be made of or include silicon oxide, silicon nitride, silicon oxynitride, carbon-containing silicon oxide, carbon-containing silicon oxynitride, carbon-containing silicon nitride, or a combination thereof. A protective material layer may be deposited and then patterned to form the protective element 120.

In some embodiments, the protective element 120 is made of a nitrogen-containing material such as silicon nitride, silicon oxynitride, and the like. The protective element 120 may also function as a stressor that induces tensile strain in the photo-sensing structure 116. The performance of the photo-sensing structure 116 may thus be improved.

As shown in FIG. 1H, a dielectric layer 126 is deposited over the semiconductor substrate 101 and the photo-sensing structure 116, in accordance with some embodiments. The dielectric layer 126 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof. The dielectric layer 126 may be deposited using a chemical vapor deposition (CVD) process, an atomic layer deposition (ALD) process, a flowable chemical vapor deposition (FCVD) process, another applicable process, or a combination thereof.

In some embodiments, before the formation of the dielectric layer 126, a contact etch stop layer is deposited over the semiconductor substrate 101 and the protective element 120. The contact etch stop layer may be made of or include silicon nitride, silicon oxynitride, silicon carbide, aluminum oxide, another suitable material, or a combination thereof.

As shown in FIG. 1I, conductive features 130A, 130B, 132A, and 132B are formed, in accordance with some embodiments. The conductive features 130A and 132A are electrically connected to the doped structure 108P through the doped structure 110P. The conductive features 130B and 132B are electrically connected to the doped structure 108N through the doped structure 110N. In some embodiments, the conductive features 130A and 130B are conductive contacts that provide electrical connections to the doped structures 110P and 110N, respectively. In some embodiments, the conductive features 132A and 132B are conductive lines. The conductive features 130A, 130B, 132A, and 132B may be made of or include copper, aluminum, tungsten, cobalt, another suitable material, or a combination thereof.

In some embodiments, a metal-semiconductor compound structure 128A is formed between the conductive feature 130A and the doped structure 110P, as shown in FIG. 1I. A metal-semiconductor compound structure 128B is formed between the conductive feature 130B and the doped structure 110N. In some embodiments, the metal-semiconductor compound structures 128A and 128B are made of or include metal silicide materials. The metal-semiconductor compound structures 128A and 128B may include the silicide of titanium, nickel, cobalt, tungsten, another suitable material, or a combination thereof.

In some embodiments, the metal-semiconductor compound structure 128A further includes p-type dopants. In some embodiments, the p-type dopants in the metal-semiconductor compound structure 128A are the same as the p-type dopants in the doped structure 110P. In some embodiments, the metal-semiconductor compound structure 128B further includes n-type dopants. In some embodiments, the n-type dopants in the metal-semiconductor compound structure 128B are the same as the n-type dopants in the doped structure 110N.

In some embodiments, one or more photolithography processes and one or more etching processes are used to form the openings that are used to contain the conductive features 130A, 130B, 132A, and 132B and the metal-semiconductor compound structures 128A and 128B. The openings expose the doped structures 110P and 110N.

Afterwards, a metal layer is deposited on the exposed portions of the doped structures 110P and 110N. A thermal operation is used to initiate the reaction between the metal layer and the doped structures 110P and 110N. As a result, the metal-semiconductor compound structures 128A and 128B are formed. In some embodiments, the thermal operation is performed after the formation of the metal layer. In some other embodiments, the thermal operation is performed during the formation of the metal layer.

In some embodiments, the portions of the metal layer that are not formed into the metal-semiconductor compound structures 128A and 128B are then removed or formed into barrier layers. Afterwards, one or more conductive material layers are formed to overfill the openings. A planarization process is the used to remove the portion of the conductive material layers that are outside of the openings. As a result, the remaining portions of the conductive material layers form the conductive features 130A, 130B, 132A, and 132B.

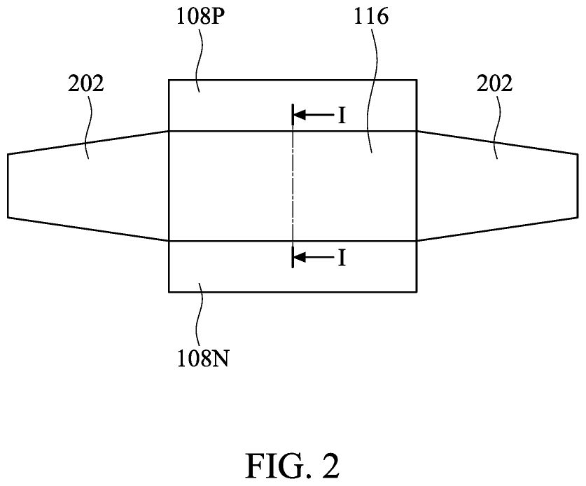

FIG. 2 is a cross-sectional view of a portion of a semiconductor device structure, in accordance with some embodiments. In some embodiments, FIG. 2 shows a horizontal cross-sectional view of a portion of a semiconductor device structure. In some embodiments, the structure shown in FIG. 1F is taken along the line I-I in FIG. 2. For clarity, some elements such as the semiconductor cap 118 and the isolation 106 are not shown in FIG. 2. In some embodiments, some portions of the semiconductor layer 104 function as a core of a waveguide structure 202. The waveguide structure 202 may further include the dielectric layer 102 and the dielectric layer 126 that is then formed.

In some embodiments, the core of the waveguide structure 202 has a first refractive index, and the structure surrounding the core has a second refractive index. The first refractive index is higher than the second refractive index. Therefore, when a light beam is directed into the waveguide structure 202, the light beam is confined within the core by total internal reflection as the light beam propagates along the length of the waveguide structure 202.

In some embodiments, the doped structure 108P, the photo-sensing structure 116, and the doped structure 108N together form a p-i-n diode. In some embodiments, the p-i-n diode is reverse biased. In some embodiments, the doped structure 108P is negatively charged, and the doped structure 108N is positively charged.

In some embodiments, light is guided by the waveguide structure 202 and incident on the photo-sensing structure 116. As a result, electron-hole pairs are generated due to the absorption of photons. These electrons and holes are separated by the electric field between the doped structures 108P and 108N that are reverse biased, and a current is produced. The magnitude of this current may be proportional to the intensity of the incident light.

In some embodiments, the photo-sensing structure 116 is in direct contact with the semiconductor cap 118. However, embodiments of the disclosure are not limited thereto. Many variations and/or modifications can be made to embodiments of the disclosure. In some other embodiments, the photo-sensing structure 116 is separated from the semiconductor cap 118 by another element.

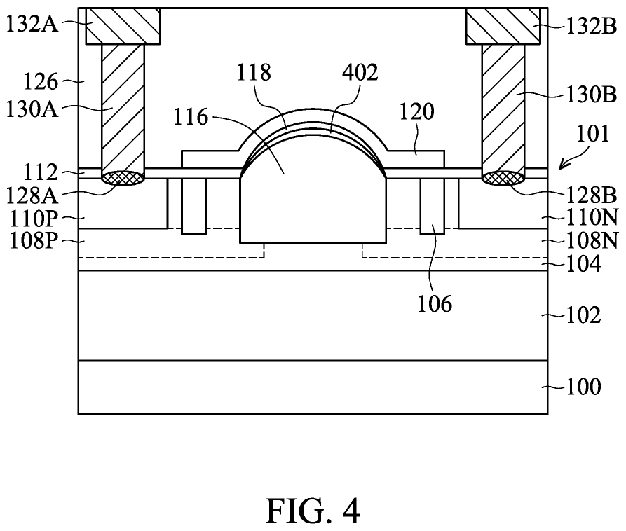

FIG. 4 is a cross-sectional view of a portion of a semiconductor device structure, in accordance with some embodiments. In some embodiments, a germanium-containing layer 402 is epitaxially grown on the photo-sensing structure 116 before the formation of the semiconductor cap 118. In some embodiments, the germanium-containing layer 402 is in direct contact with the photo-sensing structure 116. In some embodiments, the germanium-containing layer 402 is made of or include silicon germanium. In some embodiments, the photo-sensing structure 116, the germanium-containing layer 402, and the semiconductor cap 118 are epitaxially grown in-situ in the process chamber 1000.

In some embodiments, the lattice mismatch between the semiconductor cap 118 and the germanium-containing layer 402 is lower than the lattice mismatch between the photo-sensing structure 116 and semiconductor cap 118. With the buffer of the germanium-containing layer 402, defects that are cause by lattice mismatch may be significantly reduced. The performance and reliability of the photo-sensing structure 116 are improved further.

In some embodiments, the atomic concentration of germanium in the germanium-containing layer 402 is not uniform. In some embodiments, the germanium-containing layer 402 is a silicon germanium layer. In some embodiments, the atomic concentration of germanium of the silicon germanium layer gradually decreases along a direction from a bottom of the germanium-containing layer 402 towards the semiconductor cap 118.

Embodiments of the disclosure include a semiconductor device structure with a photo-sensing structure. A semiconductor cap is formed over the photo-sensing structure, so as to protect the photo-sensing structure and to prevent elements in the photo-sensing structure from diffusing into the elements around the photo-sensing structure. The semiconductor cap is p-type doped. The semiconductor cap with p-type dopants may help to reduce and/or prevent dark current generated due to the interface defect between the semiconductor cap and the photo-sensing structure. The performance and reliability of the semiconductor device structure are greatly improved.

In accordance with some embodiments, a method for forming a semiconductor device structure is provided. The method includes forming a p-type doped region and an n-type doped region in a semiconductor substrate. The method also includes partially removing the semiconductor substrate to form a recess exposing portions of the p-type doped region and the n-type doped region. The method further includes forming a photo-sensing structure over sidewalls and a bottom of the recess and forming a semiconductor cap over the photo-sensing structure. The semiconductor cap is p-type doped.

In accordance with some embodiments, a method for forming a semiconductor device structure is provided. The method includes forming a p-type doped structure and an n-type doped structure. The method also includes forming a photo-sensing structure, and a portion of the photo-sensing structure is between the p-type doped structure and the n-type doped structure. The method further includes forming a semiconductor cap over the photo-sensing structure. The semiconductor cap is p-type doped.

In accordance with some embodiments, a semiconductor device structure is provided. The semiconductor device structure includes a substrate and a p-type doped structure formed in the substrate. The semiconductor device structure also includes an n-type doped structure formed in the substrate. The semiconductor device structure further includes a photo-sensing epitaxial structure partially or completely surrounded by the substrate. A portion of the photo-sensing epitaxial structure is between the p-type doped structure and the n-type doped structure. In addition, the semiconductor device structure includes a semiconductor cap over the photo-sensing epitaxial structure, and the semiconductor cap is p-type doped.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a p-type doped region and an n-type doped region in a semiconductor substrate;
partially removing the semiconductor substrate to form a recess exposing portions of the p-type doped region and the n-type doped region;
forming a photo-sensing structure over sidewalls and a bottom of the recess; and
forming a semiconductor cap over the photo-sensing structure, wherein the semiconductor cap is p-type doped.

2. The method for forming a semiconductor device structure as claimed in claim 1, wherein the photo-sensing structure and the semiconductor cap are epitaxially grown in-situ in a process chamber, and vacuum of the process chamber is not broken during the growth of photo-sensing structure and the semiconductor cap.

3. The method for forming a semiconductor device structure as claimed in claim 2, further comprising:
epitaxial growing a silicon germanium layer on the photo-sensing structure before the formation of the semiconductor cap.

4. The method for forming a semiconductor device structure as claimed in claim 3, wherein the silicon germanium layer has an atomic concentration of germanium, and the atomic concentration of germanium gradually decreases along a direction from a bottom of the silicon germanium layer towards the semiconductor cap.

5. The method for forming a semiconductor device structure as claimed in claim 1, further comprising:
forming a nitrogen-containing stressor layer over the semiconductor cap.

6. The method for forming a semiconductor device structure as claimed in claim 5, wherein the nitrogen-containing stressor layer extends past opposite edges of the photo-sensing structure.

7. The method for forming a semiconductor device structure as claimed in claim 1, wherein the semiconductor cap is a silicon layer doped with p-type dopants.

8. The method for forming a semiconductor device structure as claimed in claim 1, wherein the semiconductor cap has a p-type dopant concentration that is within a range from about 10¹⁷ cm⁻³ to about 10¹⁹ cm⁻³.

9. The method for forming a semiconductor device structure as claimed in claim 1, wherein the p-type doped region and the n-type doped region are partially removed during the formation of the recess.

10. The method for forming a semiconductor device structure as claimed in claim 1, wherein the photo-sensing structure is formed to be protruding from a top surface of the semiconductor substrate.

11. A method for forming a semiconductor device structure, comprising:
forming a p-type doped structure and an n-type doped structure;
forming a photo-sensing structure, wherein a portion of the photo-sensing structure is between the p-type doped structure and the n-type doped structure; and
forming a semiconductor cap over the photo-sensing structure, wherein the semiconductor cap is p-type doped.

12. The method for forming a semiconductor device structure as claimed in claim 11, wherein the semiconductor cap is formed directly on the photo-sensing structure.

13. The method for forming a semiconductor device structure as claimed in claim 11, wherein edges of the semiconductor cap and the photo-sensing structure are vertically aligned with each other.

14. The method for forming a semiconductor device structure as claimed in claim 11, further comprising:
forming a dielectric protective element over the semiconductor cap, wherein the dielectric protective element extends past a first interface between the photo-sensing structure and the p-type doped structure and a second interface between the photo-sensing structure and the n-type doped structure.

15. The method for forming a semiconductor device structure as claimed in claim 11, further comprising:
forming a first conductive structure electrically connected to the p-type doped structure; and
forming a second conductive structure electrically connected to the n-type doped structure.

16. A semiconductor device structure, comprising:
a substrate;
a p-type doped structure formed in the substrate;
an n-type doped structure formed in the substrate;
a photo-sensing epitaxial structure at least partially surrounded by the substrate, wherein a portion of the photo-sensing epitaxial structure is between the p-type doped structure and the n-type doped structure; and
a semiconductor cap over the photo-sensing epitaxial structure, wherein the semiconductor cap is p-type doped.

17. The semiconductor device structure as claimed in claim 16, wherein the semiconductor cap is in direct contact with the photo-sensing epitaxial structure.

18. The semiconductor device structure as claimed in claim 16, wherein the semiconductor cap is a silicon layer doped with p-type dopants.

19. The semiconductor device structure as claimed in claim 16, wherein the semiconductor cap has a p-type dopant concentration that is within a range from about 10¹⁷ cm⁻³ to about 10¹⁹ cm⁻³.

20. The semiconductor device structure as claimed in claim 16, further comprising:
a dielectric protective element over the semiconductor cap, wherein the dielectric protective element extends past opposite edges of the semiconductor cap.
